(19) United States
(12) Patent Application Publication
(10) Pub. No.: US 2010/0291855 A1
(43) Pub. Date: Nov. 18, 2010

(54) Air conditioning system

(76) Inventors: Helmut Nonn, Malberg (DE); Tim Siegel, Houston, TX (US); Michael Nicolai, Allertshausen (DE)

Correspondence Address: Pauley Petersen & Erickson, Suite 365, 2800 W. Higgins Road, Hoffman Estates, IL, 60169, US

(21) Appl. No.: 12/660,755

(22) Filed: Mar. 1, 2010

(30) Foreign Application Priority Data
Mar. 2, 2009 (DE) 102009011006.2-34

(51) Int. Cl. H05K 5/02; F24F 7/007

(52) U.S. Cl. 454/184; 165/59

(57) ABSTRACT

An air conditioning system for a data processing system that has at least one row of server cabinets. The row of server cabinets borders a cold path. At least one air conditioning unit takes in warm air, cools it, and blows it out as cold air. The air conditioning unit is integrated into a row of server cabinets and the dimensions of the air conditioning unit and the dimensions of the server cabinets are essentially the same or, while having the same height and depth, the width of the air conditioning unit corresponds to a whole-number multiple of a width of one server cabinet. The air conditioning system can be used to produce an effective cooling concept for temperature-sensitive data processing systems, which influences the immediate surroundings only slightly with warm air. The modular construction allows the cooling capacity to be scaled, also making it possible to carry out a subsequent expansion.

### BACKGROUND OF THE INVENTION

1. Field of the Invention

This invention relates to an air conditioning system for a data processing system that has at least one row of server cabinets, the row of server cabinets borders a cold path, and at least one air conditioning unit takes in warm air, cools it, and blows it out as cold air.

2. Discussion of Related Art

Data processing systems normally include a multitude of server cabinets that have individual electronic modules or which are equipped with separate fans, cold air intakes, and warm air outlets, installed in them for cooling purposes.

The server cabinets are arranged in a plurality of rows and are oriented so that the cold air intakes and the warm air outlets of the individual server cabinets are situated or positioned in respectively opposite directions from one another and corresponding cold paths and warm paths are in alternating fashion between the server cabinets. In a two-row arrangement of server cabinets, a cold path is provided between the two server cabinet rows. The warm air outlets of the server cabinets are situated or positioned on the outside of this arrangement and blow the warm air into the surrounding space.

Various concepts are known from the prior art for air conditioning, in particular cooling, these types of data processing systems.

It is possible, for example, for the warm air exhausted from the server cabinets to be taken in by an air conditioning system, cooled, and blown into the cold path. In order to increase the cooling efficiency, the cold path normally is partitioned off from the warm paths and the surrounding space at the sides and top. Systems of this kind are described, for example, by PCT International Publication WO 03/083631 and U.S. Pat. No. 6,859,366 B2.

Particularly effective air conditioning of systems of this kind are inline air conditioning systems, which are situated between the server cabinets at particular intervals depending on the dissipation of the data processing system. These air conditioning units have fans that take in the warm air from the warm paths or the surrounding air via warm air intakes, cool the air with one or more heat exchangers through which water flows, and blow it into the partitioned-off cold paths via cold air injection points.

In the product catalog “RITTAL Handbook 32/IT Solutions”, starting on page 726 and in the information brochure “RITTAL IT-Cooling Solutions”, 03/08, for example, appropriate air conditioning units are listed under the trademark “LCP Inline”.

LCP stands for liquid cooling package and describes air conditioning units that can be placed between server cabinets inside data processing systems and that have water-cooled heat exchangers.

The air conditioning systems currently on the market have one disadvantage because they represent an interruption in the server cabinet arrangement and their structure diverges significantly from that of the server cabinets.

### SUMMARY OF THE INVENTION

One object of this invention is to provide an air conditioning system with a structure that allows it to be fully integrated into a data processing system.

This object is achieved with an air conditioning unit integrated into the row of cabinets and the dimensions of the air conditioning unit and the dimensions of the server cabinets are essentially the same or, while having the same height and depth, the width of the air conditioning unit corresponds to a whole-number multiple of a width of one server cabinet.

By contrast with centrally installed air conditioning systems, this air conditioning system makes it possible for warm air to be extracted directly at its point of origin and supplied back to the cold path in the form of cold air. Air pressure losses and thus the power consumption of the fans are minimized because only short flow lengths are taken into account. In addition, the surroundings of the data processing system are only slightly influenced by warm air, yielding an effective cooling concept for temperature-sensitive data processing systems. It is advantageous if each air conditioning unit has the same dimensions as the server cabinets, and it can be integrated directly into the rows of server cabinets without a need to interrupt the grid arrangement for the server cabinets.

It is advantageous for the air conditioning unit to have at least one base module and possibly additional expansion modules, with the number of expansion modules adapted as a function of the required cooling capacity for the data processing system.

In a preferred embodiment, the dimensions of the base module and the expansion modules of the air conditioning unit are essentially the same. The dimensions of the base module and the expansion modules correspond to those of one server cabinet. In particular, this relates to the depth and width of the base modules and expansion modules. This modular construction allows the cooling capacity to be optionally scaled, also making it possible to have a subsequent expansion. In addition, this concept can also be used to achieve a redundancy in the air conditioning system, for example when at least two base modules are installed in a data processing system.

The air conditioning units can be used in various ways if cold air can be conveyed vertically downward via at least one cold air discharge, through a double floor and into the cold path or can be conveyed horizontally via perforated front elements of the air conditioning unit and into the cold path.

With a horizontal cold air discharge into the cold path, devices for slowing the flow of air are preferably provided on the air outlet side in both the base module and the expansion modules. This can be implemented, for example, with a positive pressure plenum that is situated or positioned in the flow direction directly between the exhaust opening of the fan and the perforated front elements of the air conditioning unit. With direct cold path injection, it is thus possible for the air flow to be reduced to a certain quantity and also to be homogenized.

With a variability in the intake of warm air, it is possible for the warm air to be taken in by at least one warm air intake, for example via a perforated rear-wall door and/or at the top of the air conditioning unit. With a horizontal extraction at the rear, it is possible, for example, for the warm air to also be taken in directly from a warm path partition, making it possible to achieve a particularly effective cooling of the data processing system.

In one embodiment of the air conditioning system, all of the upper-level components of the air conditioning unit are installed in the base module. Thus, for example, the base module of the air conditioning unit has at least one heat exchanger that has a connection to water-conveying systems and a control unit for fans and the water circuit.

The expansion module of the air conditioning unit has at least one heat exchanger and at least one fan. Both the fan and the water circuit for the heat exchangers of the expansion module can be controlled from the control unit of the base module and for this purpose, the base module has appropriate interfaces for connecting to the expansion modules. The expansion module performs the function of increasing the cooling capacity of the air conditioning unit and is appropriately controlled from the base module. It can also be supplied with cooling water. This is accompanied by cost savings in the installation of such air conditioning systems. With this concept, additional expansion modules can be subsequently arranged in a line with each existing unit at any time.

If the heat exchanger in the base module or expansion modules of the air conditioning unit is installed diagonally when viewed from the side, then a larger heat exchange area is available for the cooling. In this case, it is possible for the heat exchanger to extend across essentially the entire diagonal, viewed from the side, of the interior of the air conditioning unit.

In a preferred embodiment, the heat exchangers of the base module and expansion modules of the air conditioning unit have a filter on the inlet side, which can filter the intake air in order to remove dust particles from the air. It is thus possible to significantly reduce exposure of the data processing system to dust. In this case, the filter can be formed as a cartridge filter, which facilitates a rapid filter replacement.

If the base module of the air conditioning unit has a steam humidifier that can be controlled by the control unit, then it is also possible to influence the relative humidity.

If the fans are formed as EC ventilators, electronically commutated, then highly efficient, speed-controllable fans are used, which in comparison to classic asynchronous motors, have advantages with regard to a higher efficiency over broad speed ranges and with regard to a universal use. For example, it is not necessary to have different variants if the fans must operate with 50 Hz or 60 Hz. In the present field of use, the EC ventilators each has a respective impeller housing to facilitate changing the discharge direction.

If the cold path is partitioned off from the surrounding air, then it is possible to significantly increase the cooling efficiency of the data processing system. This also yields a better control of the flow conditions.

### BRIEF DESCRIPTION OF THE DRAWINGS

This invention is explained in greater detail below in view of an exemplary embodiment shown in the drawings, wherein:

FIG. 1 is a top view of a data processing system with an integrated air conditioning unit, according to one embodiment of this invention;

FIG. 2 is a front view of another data processing system, according to another embodiment of this invention;

FIG. 3 is a side view of the data processing system shown in FIG. 2;

FIG. 4 is a top view of another data processing system with two integrated air conditioning units, each formed as a base module;

FIG. 5 is a top view of a data processing system according to another embodiment of this invention, with two integrated air conditioning units, each formed as a base module and each having two additional expansion modules; and

FIG. 6 is a schematic view of the air conditioning unit.

### DETAILED DESCRIPTION OF THE INVENTION

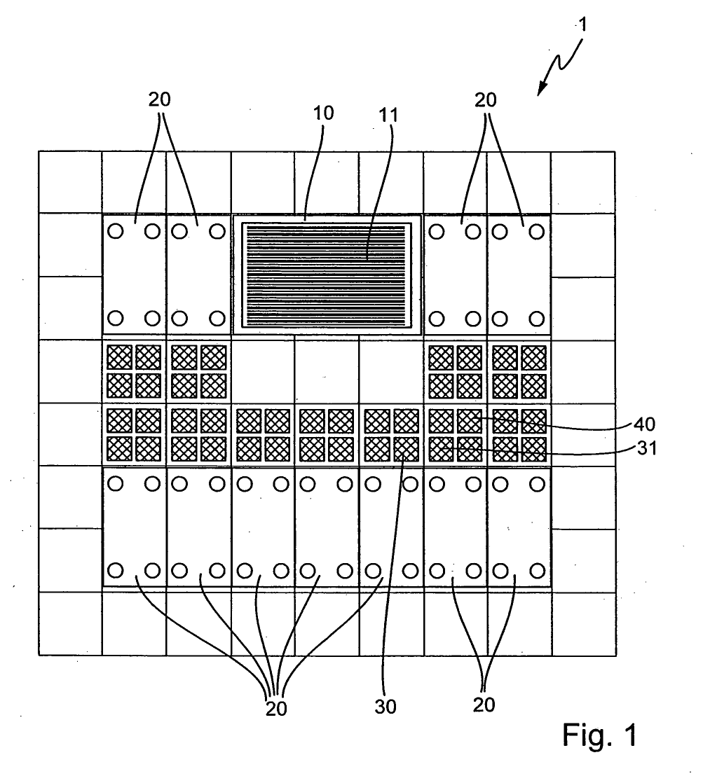

FIG. 1 is a top view of a data processing system 1 with an integrated air conditioning unit 10. The data processing system 1 in the example shown is embodied as or in the form of a two-row arrangement of server cabinets 20 that enclose a cold path 40. The cold path 40 can be partitioned off from the surrounding space in order to increase the cooling efficiency. Thus there are door and ceiling partitions which are not shown in FIG. 1. The server cabinets 20 and the air conditioning unit 10 rest on a floor 30, which is embodied in the form of a double floor and via which cold air can be conveyed into the cold path 40 via ventilation grids 31 in the floor 30. In this instance, the air conditioning unit 10 is integrated into one row of server cabinets 20 and in the example shown, corresponds exactly to the footprint of three server cabinets 20. In this view, openings that serve as a warm air intake 11 are shown on top of the air conditioning unit 10.

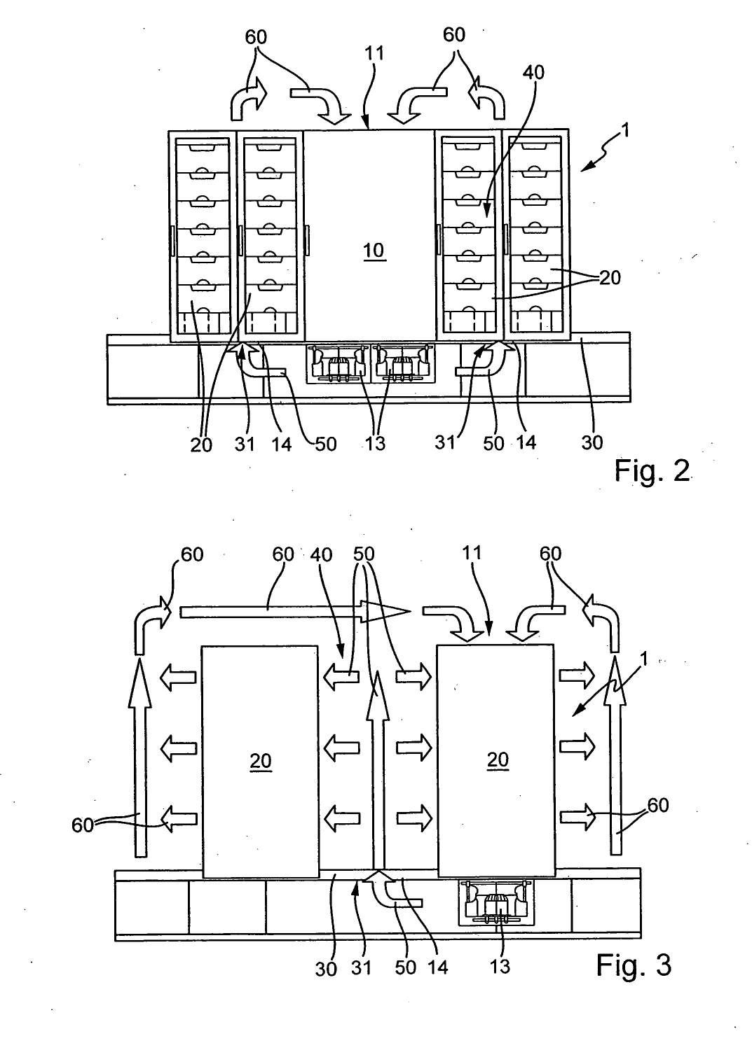

FIG. 2 is a front view of another data processing system 1. The air conditioning unit 10 in the example shown is also integrated into one row of server cabinets 20 and its dimensions correspond to those of two server cabinets 20.

FIG. 2 shows a cold air flow 50 and a warm air flow 60. The warm air rising from the server cabinets 20 is taken in by the air conditioning unit 10 via the warm air intake in a top region of the air conditioning unit 10 and via a cold air discharge 14, is conveyed by fans 13 through the floor 30 which is embodied as a double floor, and is conveyed via ventilation grids 31 into the cold path 40.

In FIG. 3, the data processing system 1 from FIG. 2 is shown from the side. The drawing shows the cold air flows 50 and warm air flows 60. The server cabinets 20 are arranged in two rows and oriented so that the cold air intakes and warm air outlets of the individual server cabinets 20 are situated in respectively opposite directions from one another. In this two-row arrangement of the server cabinets 20, the cold path 40 is situated between the two rows of server cabinets. The warm air outlets of the server cabinets 20 are situated or positioned on the outside of this arrangement and blow the warm air into the surrounding space.

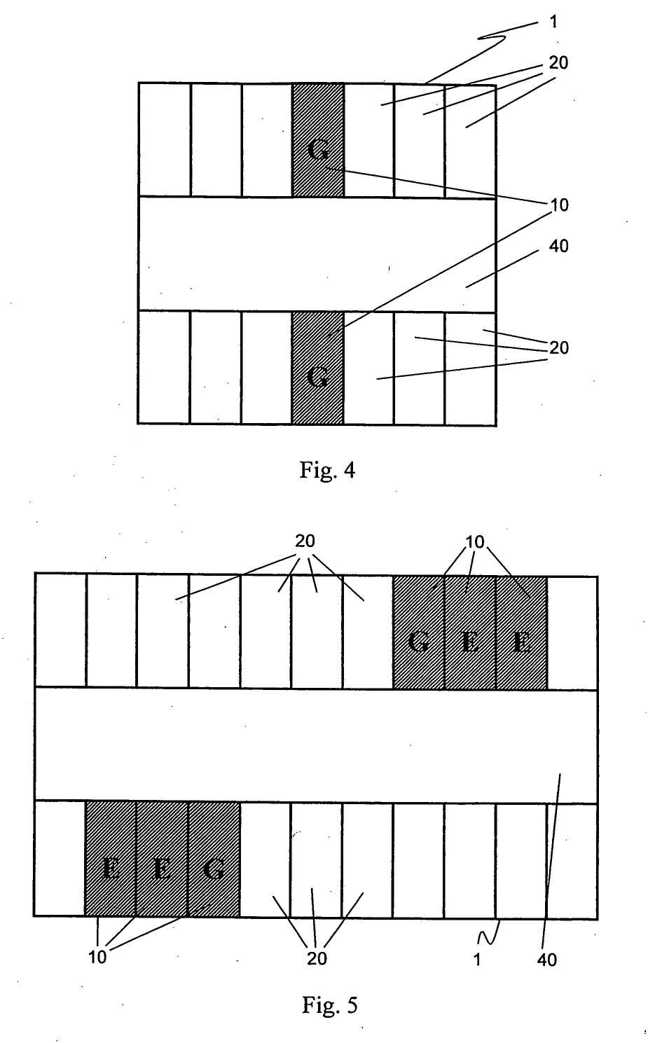

FIGS. 4 and 5 are schematic top views of other arrangements of different sizes of data processing system 1, in each of which the server cabinets 20 are respectively arranged in two rows and a partitioned-off cold path 40 is provided between the rows.

FIG. 4 shows an arrangement in which a respective base module, labeled with a “G”, of each air conditioning unit 10 is integrated into one row of server cabinets 20. In FIG. 5, because the data processing system 1 is larger, an increased cooling capacity is required. In this example, the base module of each air condition unit 10 is associated with two respective expansion modules, labeled with an “E”.

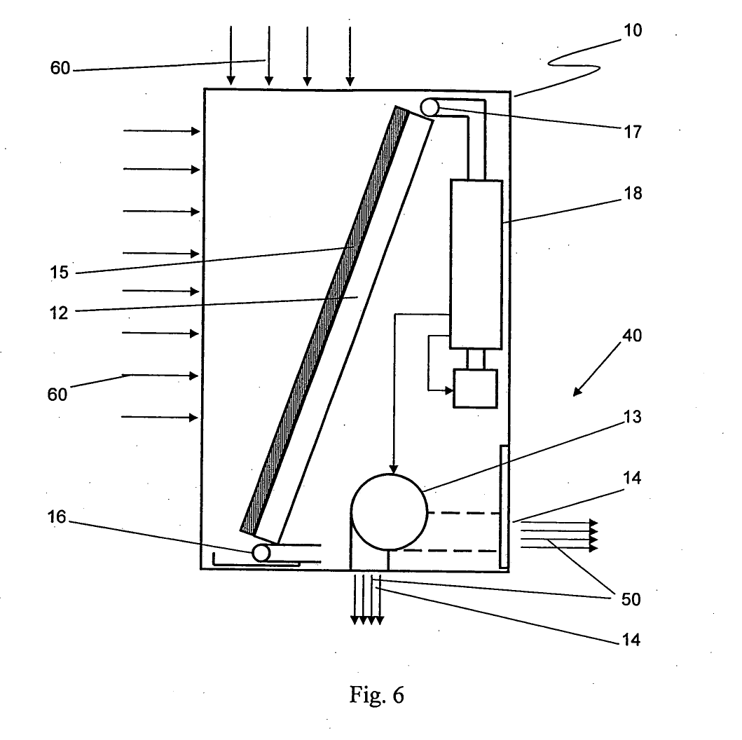

FIG. 6 shows a schematic sectional view of the air conditioning unit 10 and its main components. FIG. 6 also shows the cold air flows 50 and warm air flows 60. The warm air can travel both horizontally through a perforated door attached to the rear or vertically from above through an opening provided in a top plate. It is also possible to install an air duct or a housing extension.

The warm air, which is taken in by the fans 13, first flows through a heat exchanger 12 arranged diagonally in the housing of the air conditioning unit 10 and is cooled in the process. On the inlet side, the heat exchanger 12 is associated with a filter 15 that can be formed as a cartridge filter. Each fan 13 is formed as EC radial ventilators and, depending on the intended use, can blow the cold air vertically downward via a cold air discharge 14 into the cold path 40 in a double floor or can blow the cold air horizontally via perforated front elements, for example via a perforated front door, of the air conditioning unit 10, directly into the cold path 40. To accomplish this, the fans 13 can be installed or positioned in different directions in the air conditioning unit 10. In this case, devices such as a positive pressure plenum can be provided at the air outlet end to slow down the air flow.

The heat exchangers 12 are connected to a cooling water system and have corresponding distributors 16 and collectors 17. A control unit 18 regulates the cooling water circuit and the flow rate of the fans 13.

In the base module of the air conditioning unit 10, there is a connection to an external water circuit. The base module of the air conditioning unit 10 also has interfaces that can be connected to expansion modules for expanding the cooling capacity of the air conditioning unit 10. The interfaces relate in particular to the control of the cooling water circuit and the actuation of the fan 13 in the expansion module, which does not have a control unit.

The control unit 18 can have a differential pressure control of the fan output of the fans 13. It is also possible to provide a control of the relative humidity by a steam humidifier. Also, additional fans 13, which are situated for example in the vicinity of the double floor, see FIGS. 2 and 3, can also be controlled, thus making it possible to control the rate of air flow through the air conditioning system.

The air conditioning system of this invention can be used to produce an effective cooling concept for temperature-sensitive data processing systems, which influences the immediate surroundings only slightly with warm air. The modular construction allows the cooling capacity to be scaled, also making it possible to carry out a subsequent expansion.

German Patent Reference 10 2009 011 006.2-34, filed 2 Mar. 2009, the priority document corresponding to this invention, to which a foreign priority benefit is claimed under Title 35, United States Code, Section 119, and its entire teachings are incorporated, by reference, into this specification.

What is claimed is:

1. An air conditioning system for a data processing system (1) having at least one row of server cabinets (20), the at least one row of server cabinets (20) bordering a cold path (40), and at least one air conditioning unit (10) taking in warm air, cooling the warm air and blowing out cold air, the air conditioning system comprising the at least one air conditioning unit (10) integrated into the at least one row of server cabinets (20) and first dimensions of the air conditioning unit (10) being essentially the same as second dimensions of the server cabinets (20) or with a same height and a same depth, a width of the air conditioning unit (10) corresponding to a whole-number multiple of a width of one of the server cabinets (20).

2. The apparatus as recited in claim 1, wherein the at least one air conditioning unit (10) comprises at least one base module and at least one expansion module, and a number of expansion modules adapted as a function of a required cooling capacity for the data processing system (1).

3. The apparatus as recited in claim 2, wherein third dimensions of the base module are essentially the same as fourth dimensions of the expansion modules of the air conditioning unit (10).

4. The apparatus as recited in claim 3, wherein the third dimensions of the base module and the fourth dimensions of the expansion modules of the air conditioning unit (10) correspond to the second dimensions of one of the server cabinets (20).

5. The apparatus as recited in claim 4, wherein the cold air is conveyed vertically downward through at least one cold air discharge (14), through a double floor, and into the cold path (40) or is conveyed horizontally through perforated front elements of the air conditioning unit (10) and into the cold path (40).

6. The apparatus as recited in claim 5, wherein with the at least one horizontal cold air discharge (14) into the cold path (40), devices for slowing' a flow of air provided at an air outlet side in both the base module and the expansion modules.

7. The apparatus as recited in claim 6, wherein the warm air is taken in by at least one warm air intake (11) through openings at a rear and/or a top of the air conditioning unit (10).

8. The apparatus as recited in claim 7, wherein the base module of the air conditioning unit (10) has at least one heat exchanger (12) with a connection to water-conveying systems and a control unit (18) for fans (13) and a water circuit.

9. The apparatus as recited in claim 8, wherein one of the expansion modules of the air conditioning unit (10) has the at least one heat exchanger (12) and at least one of the fans (13) and both the fan (13) and the water circuit for the heat exchanger (12) of the expansion module is controllable from the control unit (18) of the base module and the base module has appropriate interfaces for connecting to the expansion modules.

10. The apparatus as recited in claim 9, wherein the at least one heat exchanger (12) in the base module or the expansion modules of the air conditioning unit (10) is installed diagonally when viewed from a side.

11. The apparatus as recited in claim 10, wherein the heat exchanger (12) of the base module and the expansion modules of the air conditioning unit (10) have a filter (15) on an inlet side.

12. The apparatus as recited in claim 11, wherein the filter (15) is formed as a cartridge filter.

13. The apparatus as recited in claim 12, wherein the base module of the air conditioning unit (10) has a steam humidifier controllable by the control unit (18).

14. The apparatus as recited in claim 13, wherein the fans (13) are formed as electronically commutated ventilators.

15. The apparatus as recited in claim 14, wherein the cold path (40) is partitioned off from a surrounding air.

16. The apparatus as recited in claim 1, wherein third dimensions of the base module are essentially the same as fourth dimensions of the expansion modules of the air conditioning unit (10).

17. The apparatus as recited in claim 1, wherein third dimensions of the base module and fourth dimensions of the expansion modules of the air conditioning unit (10) correspond to the second dimensions of one of the server cabinets (20).

18. The apparatus as recited in claim 1, wherein the cold air is conveyed vertically downward through at least one cold air discharge (14), through a double floor, and into the cold path (40) or is conveyed horizontally through perforated front elements of the air conditioning unit (10) and into the cold path (40).

19. The apparatus as recited in claim 18, wherein with the at least one horizontal cold air discharge (14) into the cold path (40), devices for slowing a flow of air provided at an air outlet side in both the base module and the expansion modules.

20. The apparatus as recited in claim 1, wherein the warm air is taken in by at least one warm air intake (11) through openings at a rear and/or a top of the air conditioning unit (10).

21. The apparatus as recited in claim 1, wherein the base module of the air conditioning unit (10) has at least one heat exchanger (12) with a connection to water-conveying systems and a control unit (18) for fans (13) and a water circuit.

22. The apparatus as recited in claim 1, wherein one of expansion modules of the air conditioning unit (10) has at least one heat exchanger (12) and at least one of fans (13) and both the fan (13) and the water circuit for the heat exchanger (12) of the expansion module is controllable from a control unit (18) of the base module and the base module has appropriate interfaces for connecting to the expansion modules.

23. The apparatus as recited in claim 8, wherein the at least one heat exchanger (12) in the base module or the expansion modules of the air conditioning unit (10) is installed diagonally when viewed from a side.

24. The apparatus as recited in claim 1, wherein a heat exchanger (12) of the base module and the expansion modules of the air conditioning unit (10) have a filter (15) on an inlet side.

25. The apparatus as recited in claim 24, wherein the filter (15) is formed as a cartridge filter.

26. The apparatus as recited in claim 1, wherein the base module of the air conditioning unit (10) has a steam humidifier controllable by the control unit (18).

27. The apparatus as recited in claim 1, wherein fans (13) are formed as electronically commutated ventilators.

28. The apparatus as recited in claim 1, wherein the cold path (40) is partitioned off from a surrounding air.
